(19) United States
(12) Patent Application Publication
(10) Pub. No.: US 2016/0096966 A1
(43) Pub. Date: Apr. 7, 2016

(54) PRINTING AREA OF A DISPLAY APPARATUS

(71) Applicant: Samsung Display Co., Ltd., Yongin-city (KR)

(72) Inventor: Sein CHANG, Yongin-City (KR)

(21) Appl. No.: 14/708,806

(22) Filed: May 11, 2015

(30) Foreign Application Priority Data
Oct. 6, 2014 (KR) 10-2014-0134482

(51) Int. Cl. C09D 11/03; H05K 5/00; B01J 20/26

(52) U.S. Cl. CPC C09D 11/03; B01J 20/261; H05K 5/0017; C08K 2003/262

(57) ABSTRACT

A display apparatus includes a display area displaying content and a printing area located outside the display area and covering an area other than the display area. The printing area includes a window and an ink layer that is formed by dissolving potassium carbonate powder in a curable resin.

### CROSS-REFERENCE TO RELATED APPLICATION

This application claims priority from and the benefit of Korean Patent Application No. 10-2014-0134482, filed on Oct. 6, 2014, which is hereby incorporated by reference for all purposes as if fully set forth herein.

### BACKGROUND

1. Field

Exemplary embodiments relate to a display apparatus.

2. Discussion of the Background

Along with the development of information technology, the market for display apparatuses, which are media connecting users and information, has expanded. Accordingly, flat panel displays (FPDs), such as liquid crystal displays (LCDs), organic light-emitting devices (OLEDs), and plasma display panels (PDPs), are widely used.

A display apparatus may generally includes a display area, wherein content is displayed on a screen having a peripheral bezel line, and a printing area, which is a peripheral area where images are not displayed. Much research has been conducted to increase the display area and the printing area. The printing area may include an ink layer distinguishable from the display area. As light may be blocked by the ink layer, the printing area may be distinguished from the display area.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a display apparatus.

Additional aspects will be set forth in the detailed description which follows, and, in part, will be apparent from the disclosure, or may be learned by practice of the inventive concept.

According to one or more exemplary embodiments, a display apparatus includes a display area displaying content and a printing area located outside the display area and covering an area other than the display area. The printing area includes a window and an ink layer that is formed by dissolving potassium carbonate powder in a curable resin.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a top plan view of a display apparatus according to an exemplary embodiment.

FIG. 2 is a schematic sectional view of an exemplary embodiment of the printing area of the display apparatus cut along the line A-A′ of FIG. 1.

FIG. 3 is a schematic sectional view of another exemplary embodiment of the printing area of the display apparatus cut along the line A-A′ of FIG. 1.

FIG. 4 is a schematic sectional view of another exemplary embodiment of the printing area of the display apparatus cut along the line A-A′ of FIG. 1.

### DETAILED DESCRIPTION

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

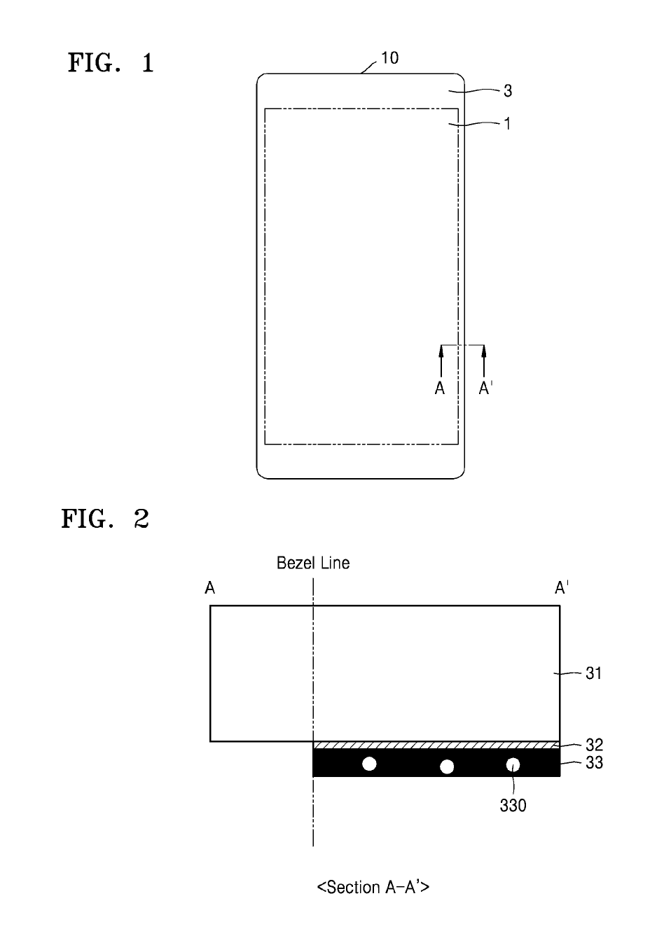

FIG. 1 is a top plan view of a display apparatus 10 according to an exemplary embodiment. FIG. 2 is a schematic sectional view of an exemplary embodiment of the printing area of the display apparatus cut along the line A-A′ of FIG. 1.

As shown in FIG. 1, the display apparatus 10 according to the present embodiment may include a display area 1 that displays content and a printing area 3 that is a peripheral portion outside of the display area 1. The printing area 3 is distinguished from the display area 1 and may cover areas of the display apparatus 10 other than the display area 1.

As shown in FIG. 2, the printing area 3 may include a window 31 that is provided at the uppermost layer, and an ink layer 33 that is provided under the window 31 and is formed by using ink, such as a curable resin, to cover the areas of the display apparatus other than the display area 1.

Also, a first attachment layer 32 may be further included between the window 31 and the ink layer 33 to attach the window 31 and the ink layer 33.

The window 31 may be formed by using a material such as a glass substrate, but is not limited thereto. The window 31 may be formed of any material that may function as the uppermost layer of the display apparatus.

The ink layer 33 may be formed of a thermo-hardening type acrylic resin coating that may be formed by using an acrylic resin and a curable resin.

The acrylic resin that is used for the thermo-hardening type acrylic resin coating may be a polymer that is formed by copolymerizing a monomer containing an active functional group, such as acrylic acid ester, methacrylic acid ester, or styrene. The active functional group may include —NH₂, —NH, —CH₂OH, —COOH, —OH, —CH, ═CH₂, or epoxy.

The curable resin may be determined according to the active functional group of the acrylic resin, for example, amino resin, epoxy resin, alkyd resin, polyamine, or acid anhydride, but is not limited thereto.

The acrylic resin and the curable resin are not limited to the embodiments above.

During a process of forming the printing area 3 by stacking the window 31 and the ink layer 33, the thermo-hardening type acrylic resin coating may not be sufficiently cured by using the curable resin, and thus age-hardening may occur. As a result, if age hardening proceeds, gas may be generated inside the printing area 3.

Also, if additional elements for blocking external impurities other than the window 31 and the ink layer 33 are stacked, air holes for dissipating gas inside the printing area 3 may be blocked. This may cause gas bubbles to be generated on the printing area 3.

In order to solve the problem described above, potassium carbonate (K₂CO₃) powder 330 may be dissolved in the curable resin of the ink layer 33 of the display apparatus according to the present embodiment.

Therefore, in the display apparatus according to the present embodiment, any gas generating in the curable resin of the ink layer 33 may be absorbed to prevent gas bubbles.

K₂CO₃ is a white powder included in the ashes of plants (e.g., “potash” from which the term potassium is derived), and has a melting point of 891° C. and a specific gravity of 2.29. K₂CO₃ is deliquescent. 105.5 g of K₂CO₃ melts in 100 g of 0° C. water, and 156 g of K₂CO₃ melts in 100 g of 100° C. water. The aqueous solution show basicity by hydrolysis, and has pH 11.6. When K₂CO₃ is crystallized in the aqueous solution, a dihydrate, such as K₂CO₃ or 2H₂O, is formed.

Other than a dihydrate, a monohydrate, a sesquihydrate, and the like are known. K₂CO₃ does not melt in ethanol, but generates carbon dioxide (CO₂) when K₂CO₃ is used for a reaction with acid. (K₂CO₃+H₂SO₄→K₂SO₄+H₂O+CO₂↑) Also, if K₂CO₃ absorbs carbon dioxide, K₂CO₃ is changed to potassium bicarbonate. 45% to 50% potassium hydroxide solution is added to a reactor, and CO₂ is added during stirring to produce a potassium carbonate solution. The potassium carbonate solution is filtered, and the filtered potassium carbonate solution is evaporated and dried, or CO₂ is added thereto again to crystallize the filtered potassium carbonate solution into potassium bicarbonate. Crystals are obtained by decomposing with heat in a revolving furnace.

Alternatively, a method similar to the Leblanc process that is used when producing sodium carbonate. That is, instead of sodium chloride, potassium chloride and concentrated sulfuric acid is used for a reaction in high temperature to change them to potassium sulfate. Potassium sulfate is reduced to carbon, changed to potassium sulfate (K₂S), and then when calcium carbonate (CaCO₃) is added, K₂CO₃ and calcium sulfide (CaS) are formed (K₂S+CaCO₃→K₂CO₃+CaS). When the product is soaked in water, K₂CO₃ melts. Then, the product is filtered, evaporated, and dried. Sodium carbonate may be used as ingredients of potash soap, potash glass, or optical glass, and used in fields such as dying, tanning, photography, raw materials of analytical reagents and medical products, or chemical processes.

Since K₂CO₃ converts to potassium bicarbonate by absorbing CO₂ as described above, when the acrylic resin coating may not be sufficiently cured, gas being generated inside the printing area 3 may be absorbed during an age hardening process.

That is, in display apparatus according to the present embodiment, the K₂CO₃ powder 330 is dissolved in the curable resin, and thus, gas generated due to the age hardening process may be immediately absorbed and gas bubbles may be prevented from forming in the printing area 3.

The K₂CO₃ powder 330 may exist as particles as shown in FIG. 2. Sizes of particles of the K₂CO₃ powder 330 may be less than 10 μm. This is because a thickness of the ink layer 33 is limited and the K₂CO₃ powder 330 should be dissolved in the ink layer 33.

Also, if the sizes of the particles are excessively large, the K₂CO₃ powder 330 may not be easily dissolved in a stacked structure of the printing area 3. Therefore, the particles of the K₂CO₃ powder 330 which are less than 10 μm may be dissolved in the curable resin.

The particles of the K₂CO₃ powder 330 may have a spherical shape as shown in FIG. 2, but are not limited thereto, and may have various irregular shapes.

Also, although not illustrated, the K₂CO₃ powder 330 may be completely dissolved in the curable resin.

Even when the K₂CO₃ powder 330 is not existing as particles having predetermined shapes and sizes but completely dissolved in the curable resin, this is only regarded as a change in a physical property of the K₂CO₃ powder 330, and its chemical properties, including absorbing gas, are not changed.

Therefore, in a display apparatus according to another embodiment, the K₂CO₃ powder 330 may be completely dissolved in the curable resin and not have a particular shape.

The display apparatus according to the present embodiment may additionally include a surfactant (not shown) that dissolves the K₂CO₃ powder 330 in the ink layer 33.

The K₂CO₃ powder 330 may not be easily dissolved in the ink layer 33 that is formed of the thermo-hardening type acrylic resin coating formed by using the acrylic resin and the curable resin. In this case, a surfactant may be used that dissolves the K₂CO₃ powder 330.

When the surfactant is included, less time is required to dissolve the K₂CO₃ powder 330 in the ink layer 33, and the particles of the K₂CO₃ powder 330 may be reduced in size.

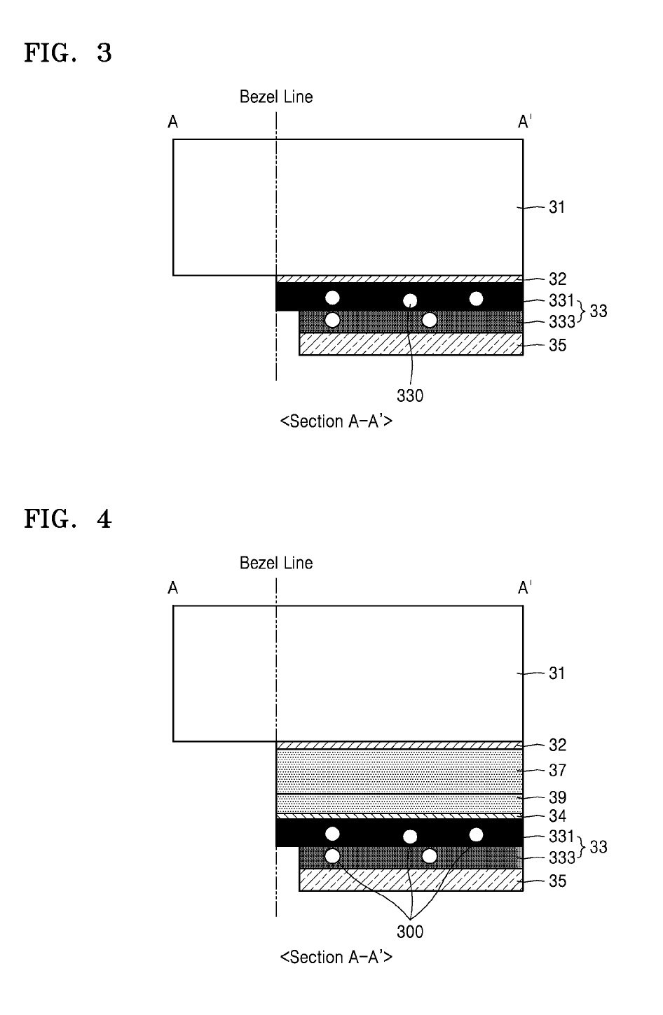

FIG. 3 is a schematic sectional view of another exemplary embodiment of the display apparatus cut along the line A-A′ of FIG. 1.

The display apparatus according to the present embodiment may include the window 31 and the ink layer 33 that is provided under the window 31. The ink layer 33 may include a first ink layer 331 and a second ink layer 333.

The ink layer 33 may not be formed as a single ink layer, but as shown in FIG. 3, formed of the first ink layer 331 provided under the window 31 and the second ink layer 333 provided under the first ink layer 331.

If the ink layer 33 is formed as two layers, not only penetration of external impurities may be prevented more efficiently, but also, light may be more effectively blocked by the ink layer 33.

Also, since the ink layer 33 displays colors to distinguish the display area 1, the ink layer 33 may function better by including the first ink layer 331 and the second ink layer 333.

The display apparatus according to the present embodiment may include the K₂CO₃ powder 330 in at least one selected from the first ink layer 331 and the second ink layer 333.

That is, the K₂CO₃ powder 330 may be included in the first ink layer 331, the second ink layer 333, or in both.

Although FIG. 3 illustrates an embodiment in which the K₂CO₃ powder 330 is dissolved in both of the first ink layer 331 and the second ink layer 333, the embodiments are not limited thereto.

If the K₂CO₃ powder 330 is dissolved in both of the first ink layer 331 and the second ink layer 333, there is a higher ratio of the K₂CO₃ powder 330 that is dissolved per unit area, and thus, generating less amount of gas.

As shown in FIG. 3, the display apparatus according to the present embodiment may additionally include a protection ink layer 35 under the second ink layer 333.

The protection ink layer 35 may be included in the lowermost portion of a stacked structure to block external impurities from penetrating into the stack as multiple layers are stacked.

In general, if a plurality of layers form a stacked structure and the protection ink layer 35 is stacked at the lowermost portion, the protection ink layer 35 may block holes that dissipate gas and thus gas bubbles may be generated in the printing area 3.

However, in the display apparatus according to the present embodiment, the K₂CO₃ powder 330 dissolved in the ink layer 33 reduces gas generation, which in turn reduces the number of gas bubbles in the ink layer 33 even when the protection ink layer 35 is provided.

The display apparatus according to the present embodiment may add sterically hindered cyclic amine to the K₂CO₃ powder 330 in the ink layer 33. If the sterically hindered cyclic amine is added to the K₂CO₃ powder 330, CO₂ may be absorbed at higher rate.

In particular, the K₂CO₃ powder 330 containing the sterically hindered cyclic amine may be included in the ink layer 33 at a ratio of at most 16 wt % of the K₂CO₃ powder 330 and at most 10 wt % of the sterically hindered cyclic amine. The ratio of the K₂CO₃ powder 330 and the sterically hindered cyclic amine in the ink layer 33 is not limited thereto.

The sterically hindered cyclic amine added to the K₂CO₃ powder 330, may absorb CO₂ fast, reduce renewable energy, and prevent salt production and phase separation.

The sterically hindered cyclic amine includes various compounds with an alkyl group attached to a nitrogen atom that directly reacts with carbon dioxide to provide steric effects.

In general, when a nitrogen atom of an amine is used for a reaction with CO₂ gas, CO₂ is absorbed in the form of carbamate. However, since the sterically hindered cyclic amine additive added to the K₂CO₃ powder 330 is a secondary amine with steric hindrance, CO₂ may be mainly absorbed in the form of bicarbonate rather than in the form of carbamate.

Also, when the sterically hindered cyclic amine is added to the K₂CO₃ powder 330, some additives may absorb CO₂ in the form of carbamate:

2R—NH₂(amine)+CO₂ [symbol] [R—NH—CO₂—][R—NH₃+] (Formula 1)

Subsequently, potassium cations of the K₂CO₃ powder 330 may be applied as the Coulombic force to some molecules of the additive absorbed in the form bicarbonate, as shown in Formula (2) below.

[R—NH—CO2—][R—NH3+]+H2O+K+ [symbol] [R—NH3+][HCO3−]+R—NH2+K+ (Formula 2)

Accordingly, compared to the related art, the embodiments of the present inventive concept may greatly reduce the amount of renewable energy.

That is, when only the sterically hindered cyclic amine is present, Formula (2) does not proceed and thus the amount of renewable energy is reduced by a small margin. However, when the sterically hindered cyclic amine is present together with the alkali carbonate, Formula (2) proceeds and thus the amount of renewable energy used is greatly reduced.

An alkali carbonate-based CO₂ absorbent containing a sterically hindered cyclic amine, such as the K₂CO₃ powder 330, may reduce the cost involved in capturing carbon dioxide by using a low amount of renewable energy and a high absorption rate. And because the salt production and phase separation do not occur, it may eliminate the need to replenish the absorbent supply and maintain a normal level of the procedural efficiency.

Therefore, the display apparatus according to the present embodiment may add the sterically hindered cyclic amine to the K₂CO₃ powder 330 in the ink layer 33. This may accelerate gas absorption, and may prevent gas bubbles from being generated in the printing area 3.

FIG. 4 is a schematic sectional view of another exemplary embodiment of the display apparatus cut along the line A-A′ of FIG. 1.

The display apparatus according to the present embodiment may further include a molding layer 37 that is provided between the window 31 and the ink layer 33.

The molding layer 37 may generate colors or patterns that may not be provided by using the ink layer 33. The molding layer 37 may generate different patterns according to a viewing angle of a user. The display apparatus according to the present embodiment may further include a multi-layer 39 between the molding layer 37 and the ink layer 33. Also, a second attachment layer 34 for attaching the multi-layer 39 and the ink layer 33 may be further provided.

The multi-layer 39 may be provided on the molding layer 37 and formed by alternately depositing TiO₂ and SiO₂. Like the molding layer 37, the multi-layer 39 may also generate colors and various patterns that may not be provided by using the ink layer 33.

As described above, according to the one or more of the above exemplary embodiments, an ink layer of a printing area of a display apparatus includes K₂CO₃ powder, and thus gas is not generated and gas bubbles may not be generated in a printing area.

It should be understood that the exemplary embodiments described herein should be considered in a descriptive sense only and not for purposes of limitation. Descriptions of features or aspects within each exemplary embodiment should typically be considered as available for other similar features or aspects in other exemplary embodiments.

While one or more exemplary embodiments have been described with reference to the figures, it will be understood by those of ordinary skill in the art that various changes in form and details may be made therein without departing from the spirit and scope as defined by the following claims.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A display apparatus, comprising:
a display area displaying content; and
a printing area located outside the display area and covering an area other than the display area,
wherein the printing area comprises a window and an ink layer that is formed by dissolving potassium carbonate powder in a curable resin.

2. The display apparatus of claim 1, wherein a particle size of the potassium carbonate powder is 10 μm or less.

3. The display apparatus of claim 1, wherein particles of the potassium carbonate powder have a spherical shape or an irregular shape.

4. The display apparatus of claim 1, the ink layer comprises a surfactant for dissolving the potassium carbonate powder.

5. The display apparatus of claim 1, wherein the ink layer comprises:
a first ink layer; and
a second ink layer under the first ink layer,
wherein at least one selected from the first ink layer and the second ink layer contains the potassium carbonate powder.

6. The display apparatus of claim 5, wherein the ink layer further comprises a protection ink layer under the second ink layer.

7. The display apparatus of claim 1, wherein the curable resin is formed by adding sterically hindered cyclic amine to the potassium carbonate powder.

8. The display apparatus of claim 7, wherein the curable resin contains 16 wt % or less of the potassium carbonate powder and 10 wt % or less of the sterically hindered cyclic amine.

9. The display apparatus of claim 1, wherein the printing area further comprises:
a molding layer under the window; and
a multi-layer between the molding layer and the ink layer.

10. A display apparatus, comprising:
a display area displaying content; and
a printing area located outside the display area and covering an area other than the display area,
wherein the printing area comprises a window and an ink layer, and
wherein the ink layer comprises potassium carbonate powder in a curable resin.

11. The display apparatus of claim 10, wherein a particle size of the potassium carbonate powder is 10 μm or less.

12. The display apparatus of claim 10, wherein particles of the potassium carbonate powder have a spherical shape or an irregular shape.

13. The display apparatus of claim 10, wherein the ink layer comprises:
a first ink layer; and
a second ink layer under the first ink layer,
wherein at least one selected from the first and second ink layers contains the potassium carbonate powder.

14. The display apparatus of claim 13, wherein the ink layer further comprises a protection ink layer under the second ink layer.

15. The display apparatus of claim 10, wherein the curable resin comprises sterically hindered cyclic amine.

16. The display apparatus of claim 15, wherein the curable resin contains 16 wt % or less of the potassium carbonate powder and 10 wt % or less of the sterically hindered cyclic amine.

17. The display apparatus of claim 10, wherein the printing area further comprises:
a molding layer under the window; and
a multi-layer between the molding layer and the ink layer.

18. An ink layer for a display device, comprising:
a curable resin; and
potassium carbonate powder.

19. The ink layer of claim 18, wherein the curable resin comprises sterically hindered cyclic amine.

20. The ink layer of claim 19, wherein the curable resin contains 16 wt % or less of the potassium carbonate powder and 10 wt % or less of the sterically hindered cyclic amine.
